(19) United States
(12) Patent Application Publication
(10) Pub. No.: US 2026/0143658 A1
(43) Pub. Date: May 21, 2026

(54) ELECTROMAGNETIC WAVE SHIELDING FILM AND SHIELDED PRINTED WIRING BOARD

(71) Applicant: TATSUTA ELECTRIC WIRE & CABLE CO., LTD., Osaka (JP)

(72) Inventors: Yoshiharu YANAGI, Kyoto (JP); Hiroshi TAJIMA, Kyoto (JP); Katsuma OOKURA, Kyoto (JP)

(21) Appl. No.: 19/119,494

(22) PCT Filed: Oct. 6, 2023
(86) PCT No.: PCT/JP2023/036551

§ 371 Date: Apr. 9, 2025

(30) Foreign Application Priority Data
Oct. 12, 2022 (JP) 2022-164162

(51) Int. Cl. H05K 9/00

(52) U.S. Cl. CPC H05K 9/0084; H05K 9/0022

(57) ABSTRACT

The present invention provides an electromagnetic wave shielding film in which the interlayer adhesion between the adhesive layer and the metal foil is not easily broken even when heated in the reflow process or the like. The present invention relates to an electromagnetic wave shielding film including: an adhesive layer containing a resin; and metal foil placed on the adhesive layer, the metal foil having a water vapor transmission rate of 0.40 g/(m²·day) or higher, the adhesive layer having a water content of 1.00% by weight or less.

### TECHNICAL FIELD

The present invention relates to electromagnetic wave shielding films and shielded printed wiring boards.

### BACKGROUND ART

Conventionally, an electromagnetic wave shielding film, for example, is attached to a printed circuit board such as a flexible printed circuit board (FPC) to shield it from electromagnetic waves from outside.

Known electromagnetic wave shielding films include those having a structure including an adhesive layer and metal foil as a shielding layer. A printed circuit board with such an electromagnetic wave shielding film superposed thereon is heat-pressed to attach the electromagnetic wave shielding film to the printed circuit board via the adhesive layer, thereby preparing a shielded printed circuit board. After such adhesion, components are mounted on the shielded printed circuit board by reflow soldering. Meanwhile, the printed circuit board has a structure in which a printed pattern on a base film is covered with an insulating film.

An example of such an electromagnetic wave shielding film is the shielding film disclosed in Patent Literature 1 which includes a laminate of metal foil having a thickness of 0.5 μm to 12 μm and an anisotropic conductive adhesive layer.

### CITATION LIST

### Patent Literature

Patent Literature 1: WO 2013/077108

### SUMMARY OF INVENTION

### Technical Problem

When such an electromagnetic wave shielding film is placed on a printed wiring board and then components are mounted thereon by the reflow process or the like, the interlayer adhesion between the adhesive layer and the metal foil in the electromagnetic wave shielding film is broken to cause interlayer delamination.

The interlayer delamination is presumably caused by the following mechanism.

FIG. 3A and FIG. 3B are diagrams schematically showing the mechanism of interlayer delamination between an adhesive layer and metal foil in production of a shielded printed wiring board using a conventional electromagnetic wave shielding film. As shown in FIG. 3A, an electromagnetic wave shielding film 510 including an adhesive layer 520 and metal foil 530 laminated in this order is heated by heat-pressing or reflow soldering in production of the shielded printed wiring board.

The heating generates volatile components (mainly water content) 560 from the adhesive layer 520 and other components of the electromagnetic wave shielding film 510, and the volatile components are accumulated between the adhesive layer 520 and the metal foil 530.

Rapid heating in the reflow process to mount components in the state above, for example, would expand the volatile components 560 accumulated between the adhesive layer 520 and the metal foil 530 as shown in FIG. 3B to break the interlayer adhesion between the adhesive layer 520 and the metal foil 530, causing interlayer delamination.

The present invention has been made to solve the above problems, and aims to provide an electromagnetic wave shielding film in which the interlayer adhesion between the adhesive layer and the metal foil is not easily broken even when heated in the reflow process or the like.

### Solution to Problem

The present inventors found that volatile components accumulate between the adhesive layer and the metal foil because the adhesive layer absorbs the water content and the like of the air during storage of the electromagnetic wave shielding film, and that the problem can be solved by reducing the hygroscopicity of the adhesive layer, thus arriving at the present invention.

In other words, the electromagnetic wave shielding film of the present invention includes an adhesive layer containing a resin, and metal foil placed on the adhesive layer, the metal foil having a water vapor transmission rate of 0.40 g/(m²·day) or higher, the adhesive layer having a water content of 1.00% by weight or less.

In the electromagnetic wave shielding film of the present invention whose metal foil has a water vapor transmission rate of 0.40 g/(m²·day) or higher and whose adhesive layer has a small water content of 1.00% by weight or less, the amount of volatile components generated when the electromagnetic wave shielding film is heated in the reflow process or the like is small. This makes the interlayer adhesion between the adhesive layer and the metal foil not easily broken.

In the electromagnetic wave shielding film of the present invention, the metal foil preferably has a water vapor transmission rate of 0.40 g/(m²·day) to 11000 g/(m²·day), and the metal foil more preferably has a water vapor transmission rate of 5.00 g/(m²·day) to 11000 g/(m²·day).

With the metal foil having a high water vapor transmission rate, water vapor generated when the water in the adhesive layer is heated in the reflow process or the like tends to be released to the outside through the metal foil. This makes the internal pressure in the space between the adhesive layer and the metal foil less likely to increase, thus further making the interlayer adhesion between the adhesive layer and the metal foil less easily broken.

In the electromagnetic wave shielding film of the present invention, the adhesive layer preferably contains a low water absorption filler which is a material having a lower coefficient of water absorption than the resin.

With the adhesive layer containing a low water absorption filler, the water content of the adhesive layer can be reduced, and thus the interlayer adhesion between the adhesive layer and the metal foil is not easily broken.

In the electromagnetic wave shielding film of the present invention, the low water absorption filler is preferably melamine cyanurate or an acrylic resin.

These materials have a low coefficient of water absorption and are thus suitable as materials for reducing the water content of the adhesive layer. In addition, melamine cyanurate, which is a material also used as a flame retardant, contributes to improvement of the flame retardancy of the electromagnetic wave shielding film.

In the electromagnetic wave shielding film of the present invention, the adhesive layer preferably contains the low water absorption filler in a weight percentage of 15% by weight or higher and 35% by weight or lower.

With the percentage of the low water absorption filler increased, the water content of the adhesive layer can be reduced. On the other hand, too high a percentage of the low water absorption filler may result in a low percentage of the resin, which contributes to the adhesiveness, making the adhesiveness insufficient. From this viewpoint, the adhesive layer preferably contains the low water absorption filler in a weight percentage of 15% by weight or higher and 35% by weight or lower.

In the electromagnetic wave shielding film of the present invention, preferably, the adhesive layer has a water content of 0.75% by weight to 1.00% by weight, and the metal foil has a water vapor transmission rate of 5.00 g/(m²·day) to 100 g/(m²·day).

Such a water content of the adhesive layer falling within the range above is small and the water vapor transmission rate of the metal foil is high, so that the interlayer adhesion between the adhesive layer and the metal foil is not easily broken. To increase the water vapor transmission rate of the metal foil, the metal foil may possibly be made thinner or provided with openings. However, too thin a thickness of the metal foil or too high a proportion of the openings in the metal foil may decrease the electromagnetic wave shielding characteristics. From this viewpoint, the water vapor transmission rate is preferably made high enough to prevent breakage of the interlayer adhesion between the adhesive layer and the metal foil but without reducing the electromagnetic wave shielding characteristics.

In the electromagnetic wave shielding film of the present invention, the adhesive layer is preferably a conductive adhesive layer.

With the adhesive layer being a conductive adhesive layer, the shielding characteristics of the electromagnetic wave shielding film can be improved.

The electromagnetic wave shielding film of the present invention preferably further includes an insulating layer on the metal foil.

The insulating layer can protect the metal foil and the adhesive layer. The insulating layer also can prevent contact between the metal foil and another conductive component.

The shielded printed wiring board of the present invention includes a printed wiring board and the electromagnetic wave shielding film above.

Including the electromagnetic wave shielding film in which the interlayer adhesion between the adhesive layer and the metal foil is not easily broken even when heated in the reflow process or the like, the shielded printed wiring board above can stably be used as a shielded printed wiring board.

### Advantageous Effects of Invention

The present invention can provide an electromagnetic wave shielding film in which the interlayer adhesion between the adhesive layer and the metal foil is not easily broken even when heated in the reflow process or the like.

### BRIEF DESCRIPTION OF DRAWINGS

FIG. 1 is a cross-sectional view schematically showing an example of the electromagnetic wave shielding film of the present invention.

FIG. 2 is a cross-sectional view schematically showing an example of the shielded printed wiring board of the present invention including the electromagnetic wave shielding film of the present invention.

FIG. 3A is a diagram schematically showing the mechanism of interlayer delamination between an adhesive layer and metal foil in producing a shielded printed wiring board using a conventional electromagnetic wave shielding film.

FIG. 3B is a diagram schematically showing the mechanism of interlayer delamination between the adhesive layer and the metal foil in producing the shielded printed wiring board using the conventional electromagnetic wave shielding film.

### DESCRIPTION OF EMBODIMENTS

The following specifically describes the electromagnetic wave shielding film of the present invention and the shielded printed wiring board of the present invention. The present invention, however, is not limited to the following embodiment, and can be modified and applied as appropriate within the scope that does not change the gist of the present invention.

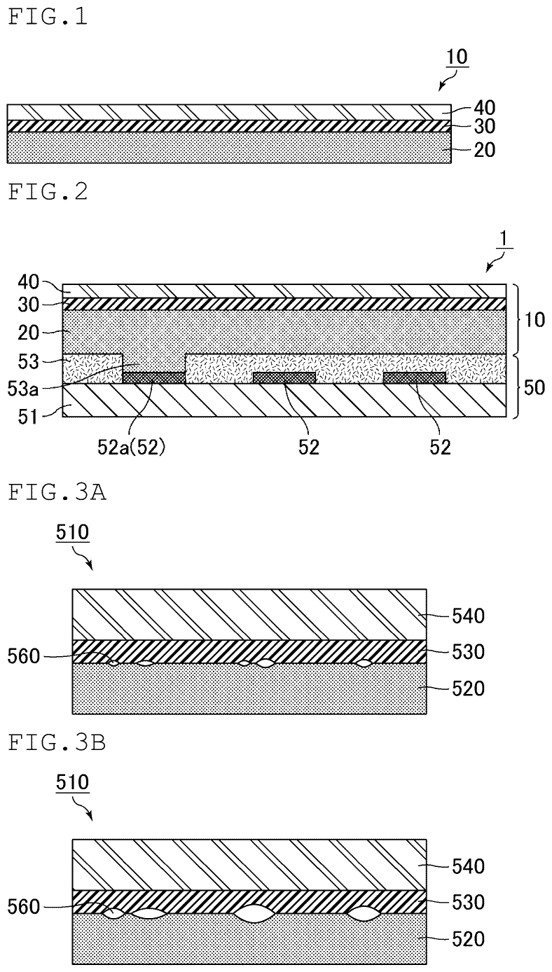

FIG. 1 is a cross-sectional view schematically showing an example of the electromagnetic wave shielding film of the present invention.

An electromagnetic wave shielding film 10 shown in FIG. 1 includes an adhesive layer 20 containing a resin, metal foil 30 placed on the adhesive layer 20, and an insulating layer 40 placed on the metal foil 30.

In the electromagnetic wave shielding film of the present invention, the adhesive layer contains a resin.

The resin may be any resin. Examples thereof include thermoplastic resin compositions such as a styrene resin composition, a vinyl acetate resin composition, a polyester resin composition, a polyethylene resin composition, a polypropylene resin composition, an imide resin composition, an amide resin composition, and an acrylic resin composition; and thermosetting resin compositions such as a phenolic resin composition, an epoxy resin composition, a urethane resin composition, a melamine resin composition, and an alkyd resin composition.

The material of the resin may contain one of these materials or may contain a combination of two or more of these.

The adhesive layer has a water content of 1.00% by weight or less.

In the electromagnetic wave shielding film whose adhesive layer has a small water content of 1.00% by weight or less, the amount of volatile components generated when the electromagnetic wave shielding film is heated in the reflow process or the like is small. This makes the interlayer adhesion between the adhesive layer and the metal foil not easily broken.

In addition, from the viewpoint of further reducing the amount of volatile components to make the interlayer adhesion between the adhesive layer and the metal foil less easily broken, the adhesive layer more preferably has a water content of 0.90% by weight or less.

The adhesive layer preferably has a water content of 0.75% by weight or more. This is because an adhesive layer having a water content of less than 0.75% by weight would not much improve the effect of making the interlayer adhesion between the adhesive layer and the metal foil not easily broken. Another reason is that, although a large amount of a low water absorption filler, which is described later, needs to be added to the adhesive layer to reduce the water content of the adhesive layer, too large an amount of the low water absorption filler added may result in an insufficient amount of the resin component, making the adhesiveness of the adhesive layer insufficient.

The water content of the adhesive layer can be measured with a Karl Fischer moisture meter in conformity with JIS K 0068 (2001).

A pretreatment of separating the adhesive layer from the electromagnetic wave shielding film and treating the adhesive layer at 23° C. and a humidity of 60% for 24 hours is performed before the water content of the adhesive layer is measured.

The adhesive layer preferably contains a low water absorption filler which is a material having a lower coefficient of water absorption than the resin.

With the adhesive layer containing a low water absorption filler, the water content of the adhesive layer can be reduced, and thus the interlayer adhesion between the adhesive layer and the metal foil is not easily broken.

In addition, the low water absorption filler is preferably a material having a coefficient of water absorption of 0.5% by weight or lower.

The coefficient of water absorption of the low water absorption filler can be measured by the Karl Fischer method in the same manner as in the measurement of the water content of the adhesive layer.

The low water absorption filler is preferably an organic filler such as melamine cyanurate or an acrylic resin.

More preferably, the low water absorption filler is melamine cyanurate. Melamine cyanurate has a low coefficient of water absorption, and is thus suitable as a material used to reduce the water content of the adhesive layer. Melamine cyanurate is a material also used as a flame retardant, and thus contributes to improvement of the flame retardancy of the electromagnetic wave shielding film.

The low water absorption filler may also be an inorganic filler such as alumina. An inorganic filler having a lower coefficient of water absorption than the resin can be selected for use from among inorganic fillers.

Examples of coefficients of water absorption of resins and low water absorption fillers that can be contained in the electromagnetic wave shielding film of the present invention include those listed below.

### Examples of Coefficients of Water Absorption of Resins

Epoxy resin: 2.0% by weight
Unsaturated polyester resin: 1.5% by weight

### Examples of Coefficients of Water Absorption of Low Water Absorption Fillers

Melamine cyanurate: 0.2% by weight
Acrylic resin: 0.5% by weight
Alumina: 0.004% by weight

The adhesive layer preferably contains the low water absorption filler in a weight percentage of 15% by weight or higher and 35% by weight or lower.

With the percentage of the low water absorption filler increased, the water content of the adhesive layer can be reduced. On the other hand, too high a percentage of the low water absorption filler may result in a low percentage of the resin, which contributes to the adhesiveness, making the adhesiveness insufficient. From this viewpoint, the adhesive layer preferably contains the low water absorption filler in a weight percentage of 15% by weight or higher and 35% by weight or lower.

The adhesive layer is preferably a conductive adhesive layer.

With the adhesive layer being a conductive adhesive layer, the shielding characteristics of the electromagnetic wave shielding film can be improved.

In the case where the adhesive layer is a conductive adhesive layer, the adhesive layer preferably contains a conductive filler.

The conductive filler is not limited, and may be metal fine particles, carbon nanotubes, carbon fibers, or metal fibers, for example.

In the case where the conductive filler is metal fine particles, the metal fine particles may be, but are not limited to, silver powder, copper powder, nickel powder, solder powder, aluminum powder, silver-coated copper powder with copper powder plated with silver, or fine particles obtained by coating polymer fine particles, glass beads, or other fine particles with metal.

Preferred among these from the viewpoint of economy is copper powder or silver-coated copper powder, which are inexpensively available.

In the case where the adhesive layer contains a conductive filler, the conductive filler content is preferably 5 to 900 parts by weight, more preferably 10 to 800 parts by weight, relative to 100 parts by weight of the resin.

The adhesive layer has a thickness of preferably 5 to 50 μm, more preferably 5 to 30 μm.

An adhesive layer having a thickness of less than 5 μm, which is thin, may decrease the adhesiveness.

An adhesive layer having a thickness of more than 50 μm, which is thick, is less contributable to the miniaturization of the electromagnetic wave shielding film.

In addition to the resin, the low water absorption filler, and the conductive filler, the adhesive layer may contain, if necessary, a curing accelerator, a tackifier, an antioxidant, a pigment, a dye, a plasticizer, a UV absorber, a defoaming agent, a leveling agent, a filler, a flame retardant, and/or a viscosity modifier.

The electromagnetic wave shielding film of the present invention includes metal foil on the adhesive layer containing a resin.

The metal foil preferably contains at least one metal selected from the group consisting of copper, silver, gold, aluminum, nickel, tin, palladium, chromium, titanium, and zinc. The metal foil may also be made of an alloy of at least two selected from the group above.

Metal foil made of any of these metals can suitably block electromagnetic waves.

The metal foil has a water vapor transmission rate of 0.40 g/(m²·day) or higher. The metal foil has a water vapor transmission rate of preferably 0.40 g/(m²·day) to 11000 g/(m²·day), more preferably 5.00 g/(m²·day) to 11000 g/(m²·day). The metal foil has a water vapor transmission rate of preferably 5.00 g/(m²·day) or higher, more preferably 20.0 g/(m²·day) or higher, still more preferably 60.0 g/(m²·day) or higher.

With the metal foil having a high water vapor transmission rate, water vapor generated when the water in the adhesive layer is heated in the reflow process or the like tends to be released to the outside through the metal foil. This makes the internal pressure in the space between the adhesive layer and the metal foil less likely to increase, thus further making the interlayer adhesion between the adhesive layer and the metal foil less easily broken.

The water vapor transmission rate may be 20000 g/(m²·day) or lower, may be 11000 g/(m²·day) or lower, or 100 g/(m²·day) or lower.

The water vapor transmission rate can be measured based on JIS K 7129-4 (2019).

To increase the water vapor transmission rate of the metal foil, the thickness of the metal foil is preferably small, preferably 6.0 μm or less, more preferably 5.0 μm or less, still more preferably 4.0 μm or less, even more preferably 3.5 μm or less.

Too small a thickness of the metal foil may decrease the strength of the metal foil. This may result in a decrease in flexural resistance. Metal foil having such a small thickness may not be able to sufficiently reflect and absorb electromagnetic waves, making the electromagnetic wave shielding film exhibit lower electromagnetic wave shielding characteristics. Therefore, the metal foil preferably has a thickness of 1.0 μm or more, more preferably 2.0 μm or more.

The metal foil may be provided with openings to have a better water vapor transmission rate. The openings can be provided by processing such as laser processing or punching processing.

Metal foil having a small thickness can be obtained by etching the metal foil. For example, rolled copper foil having a thickness of 6 μm can be etched to obtain copper foil having a thickness of 0.5 μm to 5.0 μm. The metal foil can also be provided with openings by adjusting the etching conditions.

In the electromagnetic wave shielding film of the present invention, preferably, the adhesive layer has a water content of 0.75% by weight to 1.00% by weight, and the metal foil has a water vapor transmission rate of 5.00 g/(m²·day) to 100 g/(m²·day).

Such a water content of the adhesive layer falling within the range above is small and the water vapor transmission rate of the metal foil is high, so that the interlayer adhesion between the adhesive layer and the metal foil is not easily broken. To increase the water vapor transmission rate of the metal foil, the metal foil may possibly be made thinner or provided with openings. However, too thin a thickness of the metal foil or too high a proportion of the openings in the metal foil may decrease the electromagnetic wave shielding characteristics. From this viewpoint, the water vapor transmission rate is preferably made high enough to prevent breakage of the interlayer adhesion between the adhesive layer and the metal foil but without reducing the electromagnetic wave shielding characteristics.

The electromagnetic wave shielding film of the present invention may further include an insulating layer on the metal foil.

The insulating layer is not limited as long as it has a sufficient insulating property and can protect the metal foil and the adhesive layer, and the insulating layer is preferably made of a thermoplastic resin composition, a thermosetting resin composition, or an active energy ray-curable composition, for example.

Examples of the thermoplastic resin composition include, but not limited to, a styrene resin composition, a vinyl acetate resin composition, a polyester resin composition, a polyethylene resin composition, a polypropylene resin composition, an imide resin composition, and an acrylic resin composition.

Examples of the thermosetting resin composition include, but not limited to, a phenolic resin composition, an epoxy resin composition, a urethane resin composition, a melamine resin composition, and an alkyd resin composition.

Examples of the active energy ray-curable composition include, but not limited to, a polymerizable compound having at least two (meth)acryloyloxy groups in its molecule.

The insulating layer may be made of a single material or two or more materials.

The insulating layer may include, for example, a curing accelerator, a tackifier, an antioxidant, a pigment, a dye, a plasticizer, a UV absorber, a defoaming agent, a leveling agent, a filler, a flame retardant, a viscosity modifier, and an antiblocking agent, if necessary.

The thickness of the insulating layer is not limited and can be set appropriately according to the need, and the thickness is preferably 1 to 15 μm, more preferably 3 to 10 μm.

An insulating layer having a thickness of less than 1 μm, which is too thin, may not be able to protect the metal foil and the adhesive layer sufficiently.

An insulating layer having a thickness of more than 15 μm, which is too thick, may make the electromagnetic wave shielding film not easily bend and may also have lower toughness. This makes it difficult to apply the electromagnetic wave shielding film to a member which is desired to have flexural resistance.

The electromagnetic wave shielding film of the present invention includes an insulating layer if necessary, and may not include an insulating layer.

Next, the shielded printed wiring board of the present invention including the electromagnetic wave shielding film of the present invention is described.

FIG. 2 is a cross-sectional view schematically showing an example of the shielded printed wiring board of the present invention including the electromagnetic wave shielding film of the present invention.

A shielded printed wiring board 1 shown in FIG. 2 includes a printed wiring board 50 and the electromagnetic wave shielding film 10.

The printed wiring board 50 includes a base film 51, a printed circuit 52 placed on the base film 51, and a cover lay 53 covering the printed circuit 52.

In the printed wiring board 50, the printed circuit 52 includes a ground circuit 52a, and the cover lay 53 is provided with an opening 53a through which the ground circuit 52a is exposed.

In the shielded printed wiring board 1, the electromagnetic wave shielding film 10 is placed on the printed wiring board 50, with the cover lay 53 and the adhesive layer 20 being in contact with each other.

In the shielded printed wiring board 1, the adhesive layer 20 fills the opening 53a of the cover lay 53 and is in contact with the ground circuit 52a. This configuration can improve the shielding characteristics of the electromagnetic wave shielding film 10.

The following matters are disclosed herein.

The present disclosure (1) relates to an electromagnetic wave shielding film including an adhesive layer containing a resin, and metal foil placed on the adhesive layer, the metal foil having a water vapor transmission rate of 0.40 g/(m²·day) or higher, the adhesive layer having a water content of 1.00% by weight or less.

The present disclosure (2) relates to the electromagnetic wave shielding film according to the present disclosure (1), wherein the metal foil has a water vapor transmission rate of 0.40 g/(m²·day) to 11000 g/(m²·day).

The present disclosure (3) relates to the electromagnetic wave shielding film according to the present disclosure (2), wherein the metal foil has a water vapor transmission rate of 5.00 g/(m²·day) to 11000 g/(m²·day).

The present disclosure (4) relates to the electromagnetic wave shielding film according to any one of the present disclosures (1) to (3), wherein the adhesive layer contains a low water absorption filler which is a material having a lower coefficient of water absorption than the resin.

The present disclosure (5) relates to the electromagnetic wave shielding film according to the present disclosure (4), wherein the low water absorption filler is melamine cyanurate or an acrylic resin.

The present disclosure (6) relates to the electromagnetic wave shielding film according to the present disclosure (4) or (5), wherein the adhesive layer contains the low water absorption filler in a weight percentage of 15% by weight or higher and 35% by weight or lower.

The present disclosure (7) relates to the electromagnetic wave shielding film according to any one of the present disclosures (1) to (6), wherein the adhesive layer has a water content of 0.75% by weight to 1.00% by weight, and the metal foil has a water vapor transmission rate of 5.00 g/(m²·day) to 100 g/(m²·day).

The present disclosure (8) relates to the electromagnetic wave shielding film according to any one of the present disclosures (1) to (7), wherein the adhesive layer is a conductive adhesive layer.

The present disclosure (9) relates to the electromagnetic wave shielding film according to any one of the present disclosures (1) to (8), further including an insulating layer on the metal foil.

The present disclosure (10) relates to a shielded printed wiring board including a printed wiring board, and the electromagnetic wave shielding film according to any one of the present disclosures (1) to (9) on the printed wiring board.

### EXAMPLES

The following shows an example that more specifically describes the present invention. The present invention is not limited to the example.

A conductive adhesive was produced by mixing a polyester thermosetting resin as a resin, silver-coated copper powder as a conductive filler, and melamine cyanurate particles as a low water absorption filler. The proportions of the resin and the low water absorption filler were varied as shown in Table 1 to produce multiple types of conductive adhesives. The conductive adhesives thus produced were designated as (A-1) to (A-10).

### [Water Content Measurement]

The water contents of the conductive adhesives (A-1) to (A-10) were measured with a Karl Fischer moisture meter by the method described herein. Table 1 shows the measurement results.

### [Adhesiveness Measurement]

Each of the conductive adhesives (A-1) to (A-10) was applied to 2-μm-thick copper foil to a thickness of 5 μm to produce an electromagnetic wave shielding film.

A peel test was performed using the Test Method for Peel Adhesiveness of Pressure-Sensitive Tape/Pressure-Sensitive Sheet specified in ASTM D3330. Specifically, each electromagnetic wave shielding film cut to 125 mm in length and 25 mm in width was attached to a stainless steel test panel. The tensile force when the electromagnetic wave shielding film was peeled off from the test panel in a 180° direction using a tensile tester was measured to evaluate the adhesiveness. Table 1 shows the results.

TABLE 1

| | | Conductive adhesive | | | | | | | | | |
|---|---|---|---|---|---|---|---|---|---|---|---|
| | | A-1 | A-2 | A-3 | A-4 | A-5 | A-6 | A-7 | A-8 | A-9 | A-10 |
| Resin | [wt %] | 85 | 80 | 75 | 70 | 65 | 60 | 55 | 50 | 45 | 35 |
| Conductive filler | [wt %] | 15 | 15 | 15 | 15 | 15 | 15 | 15 | 15 | 15 | 15 |
| Low water absorption filler | [wt %] | 0 | 5 | 10 | 15 | 20 | 25 | 30 | 35 | 40 | 50 |
| Water content | [wt %] | 1.56 | 1.26 | 1.02 | 0.92 | 0.89 | 0.83 | 0.79 | 0.76 | 0.70 | 0.59 |
| Adhesion | [N/cm] | 5.10 | 5.42 | 5.78 | 6.13 | 6.11 | 5.96 | 5.33 | 5.00 | 3.93 | 1.79 |

The conductive adhesives having a water content of 1.00% by weight or less, namely the conductive adhesives (A-4) to (A-10), were used to produce the electromagnetic wave shielding film of the present invention.

There was a trend that the adhesiveness improves as the amount of the low water absorption filler increases when the amount of the low water absorption filler was 0 to 20% by weight. This is presumably because melamine cyanurate, which is a highly polar material, used as the low water absorption filler exhibited a high cohesive force with the resin and conductive filler in the adhesive layer, thereby improving the adhesiveness. When the amount of the low water absorption filler was more than 20% by weight, the adhesiveness tended to decrease due to the decreased amount of the resin. In particular, the adhesiveness tended to significantly decrease when the amount of the low water absorption filler was 40% by weight or more.

### [Measurement of Water Vapor Transmission Rate of Copper Foil]

The water vapor transmission rate of each of pieces of copper foil having thicknesses of 8.0 μm, 7.0 μm, 6.0 μm, 5.0 μm, 4.0 μm, 3.0 μm, 2.0 μm, 1.0 μm, and 0.5 μm was measured based on the method described herein. Table 2 shows the measurement results.

Next, the conductive adhesives (A-1) to (A-10) were each applied onto each piece of copper foil to a thickness of 5 μm to produce an electromagnetic wave shielding film.

### [Measurement of Shielding Characteristics]

The shielding characteristics of each electromagnetic wave shielding film were measured by a coaxial tube method at a frequency of 10 GHz.

In the measurement by the coaxial tube method, the amount of attenuation of electromagnetic waves by each electromagnetic wave shielding film was measured using a coaxial tube type shielding effect measurement system available from KEYCOM Corporation under conditions of a temperature of 25° C. and a relative humidity of 30 to 50%, in accordance with ASTM D4935.

Table 2 shows the measurement results.

The shielding characteristics correlated with the thickness of the copper foil. Any type of conductive adhesive exhibited the same value when copper foil of the same thickness was used. For this reason, the shielding characteristic value [dB] is shown under the “Copper foil” column in Table 2. The higher this value, the better the shielding characteristics.

When the thickness of the copper foil was 3.0 μm or more, the shielding characteristic value was higher than 100 dB.

### [Evaluation of Occurrence of Interlayer Delamination]

Each electromagnetic wave shielding film was placed on a printed wiring board by heat pressing to obtain a shielded printed wiring board. Next, this shielded printed wiring board was left in a thermo-hygrostat at 30° C. and 60% RH for one day, and then exposed to the temperature conditions during reflow soldering to evaluate the occurrence of interlayer delamination. The temperature conditions during the solder float were set such that the maximum temperature would be 288° C. The occurrence of interlayer delamination was evaluated by floating the shielded printed wiring board in a solder bath three times and visually observing the occurrence of blistering. The wiring board was marked as: “∘ (good)” if the blistered area was less than 1% of the shielding film area; “Δ (not good)” if the blistered area was 1% or more and less than 10% of the shielding film area; or “x (bad)” if the blistered area was 10% or more of the shielding film area. Table 2 shows the results.

TABLE 2

| Copper foil | | | | | | | | | | | | |
|---|---|---|---|---|---|---|---|---|---|---|---|---|
| | Shielding | Water vapor | | | | | | | | | | |
| Thickness | characteristics | transmission rate | Conductive adhesive | | | | | | | | | |
| [μm] | [dB] | [g/(m² · day)] | A-1 | A-2 | A-3 | A-4 | 4-5 | A-6 | A-7 | A-8 | A-9 | A-10 |
| 8.0 | >100 | 0.00 | x | x | x | x | x | x | x | x | x | x |
| 7.0 | >100 | 0.20 | x | x | x | x | x | x | x | x | x | x |
| 6.0 | >100 | 0.43 | x | x | x | Δ | ∘ | ∘ | ∘ | ∘ | ∘ | ∘ |
| 5.0 | >100 | 2.15 | x | x | x | Δ | ∘ | ∘ | ∘ | ∘ | ∘ | ∘ |
| 4.0 | >100 | 5.46 | x | x | x | Δ | ∘ | ∘ | ∘ | ∘ | ∘ | ∘ |
| 3.0 | >100 | 20.3 | x | x | x | ∘ | ∘ | ∘ | ∘ | ∘ | ∘ | ∘ |
| 2.0 | 96 | 62.4 | x | x | x | ∘ | ∘ | ∘ | ∘ | ∘ | ∘ | ∘ |
| 1.0 | 85 | 10600 | x | x | x | ∘ | ∘ | ∘ | ∘ | ∘ | ∘ | ∘ |
| 0.5 | 73 | 28560 | x | x | x | ∘ | ∘ | ∘ | ∘ | ∘ | ∘ | ∘ |

Table 2 shows that the wiring boards obtained using any of the conductive adhesives (A-1) to (A-3) having a water content of more than 1.00 by weight were marked as “x” for the result of the interlayer delamination test, indicating that the interlayer adhesion between the adhesive layer and the metal foil was broken over a wide range.

Also, the wiring boards obtained using a conductive adhesive having a water content of 1.00% by weight or less and copper foil having a water vapor transmission rate of lower than 0.40 g/(m²·day) were marked as “x” for the result of the interlayer delamination test, indicating that the interlayer adhesion between the adhesive layer and the metal foil was broken over a wide range.

In contrast, the wiring boards obtained using copper foil having a water vapor transmission rate of 0.40 g/(m²·day) or higher and any of the conductive adhesives (A-4) to (A-10) having a water content of 1.00% by weight or less were marked as “Δ” or “∘” for the result of the interlayer delamination test, indicating that the interlayer adhesion between the adhesive layer and the metal foil was prevented from breakage. In particular, the wiring boards obtained using any of the conductive adhesives (A-5) to (A-10) having a water content of 0.89% by weight or less were marked as “∘” for the result of the interlayer delamination test. The wiring board obtained using the conductive adhesive (A-4) having a water content of 0.92% by weight was marked as “∘” for the result of the interlayer delamination test, owing to the use of the copper foil having a water vapor transmission rate of 5.46 g/(m²·day) or higher.

Also, the thicker the copper foil, the better the shielding characteristics.

With an adhesive having a water content of less than 1.00% by weight, an electromagnetic wave shielding film can be produced in which the interlayer adhesion between the adhesive layer and the metal foil is not easily broken even when heated in the reflow process or the like.

In addition, from the viewpoints of the other properties including the shielding characteristics and adhesion, the adhesive layer preferably has a water content of 0.75% by weight to 1.00% by weight and the metal foil preferably has a water vapor transmission rate of 5.00 g/(m²·day) to 100 g/(m²·day).

### REFERENCE SIGNS LIST

1 shielded printed wiring board
10, 510 electromagnetic wave shielding film
20, 520 adhesive layer
30, 530 metal foil
40, 540 insulating layer
50 printed wiring board
51 base film
52 printed circuit
52a ground circuit
53 cover lay
53a opening
560 volatile component

1. An electromagnetic wave shielding film comprising:
an adhesive layer containing a resin; and
metal foil placed on the adhesive layer,
the metal foil having a water vapor transmission rate of 0.40 g/(m²·day) or higher,
the adhesive layer having a water content of 1.00% by weight or less.

2. The electromagnetic wave shielding film according to claim 1,
wherein the metal foil has a water vapor transmission rate of 0.40 g/(m²·day) to 11000 g/(m²·day).

3. The electromagnetic wave shielding film according to claim 2,
wherein the metal foil has a water vapor transmission rate of 5.00 g/(m²·day) to 11000 g/(m²·day).

4. The electromagnetic wave shielding film according to claim 1,
wherein the adhesive layer contains a low water absorption filler which is a material having a lower coefficient of water absorption than the resin.

5. The electromagnetic wave shielding film according to claim 4,
wherein the low water absorption filler is melamine cyanurate or an acrylic resin.

6. The electromagnetic wave shielding film according to claim 4,
wherein the adhesive layer contains the low water absorption filler in a weight percentage of 15% by weight or higher and 35% by weight or lower.

7. The electromagnetic wave shielding film according to claim 1,
wherein the adhesive layer has a water content of 0.75% by weight to 1.00% by weight, and the metal foil has a water vapor transmission rate of 5.00 g/(m²·day) to 100 g/(m²·day).

8. The electromagnetic wave shielding film according to claim 1,
wherein the adhesive layer is a conductive adhesive layer.

9. The electromagnetic wave shielding film according to claim 1, further comprising an insulating layer on the metal foil.

10. A shielded printed wiring board comprising:
a printed wiring board; and
the electromagnetic wave shielding film according to claim 1 on the printed wiring board.
